(19) United States
(12) Patent Application Publication
(10) Pub. No.: US 2025/0320631 A1
(43) Pub. Date: Oct. 16, 2025

(54) SEED SUBSTRATE AND METHOD FOR PRODUCING GROUP III NITRIDE SEMICONDUCTOR

(71) Applicant: TOYODA GOSEI CO., LTD., Kiyosu-shi (JP)

(72) Inventors: Kazuki NISHIJIMA, Kiyosu-shi (JP); Kazuyoshi IIDA, Kiyosu-shi (JP); Masaya TAGUCHI, Kiyosu-shi (JP); Taku FUJIMORI, Kiyosu-shi (JP); Miki MORIYAMA, Kiyosu-shi (JP)

(21) Appl. No.: 19/172,144

(22) Filed: Apr. 7, 2025

(30) Foreign Application Priority Data
Apr. 15, 2024 (JP) 2024-065666

(51) Int. Cl. C30B 29/40; C30B 19/02; C30B 19/12

(52) U.S. Cl. CPC C30B 29/406; C30B 19/02; C30B 19/12

(57) ABSTRACT

A method for producing a Group III nitride semiconductor includes: preparing a seed substrate including a substrate on which plural seed crystals, each made from a Group III nitride semiconductor, are discretely disposed; and bringing the plural seed crystals into contact with a melt containing an alkali metal and a Group III metal, and dissolving nitrogen in the melt to grow a Group III nitride semiconductor on the plural seed crystals, the plural seed crystals are disposed inside a disposition region which has a predetermined plane pattern, and the disposition region has: a hexagonal region having a hexagonal shape; and at least two enlarged regions as defined herein.

### CROSS-REFERENCE TO RELATED APPLICATION

This application is based on and claims priority under 35 USC 119 from Japanese Patent Application No. 2024-065666 filed on Apr. 15, 2024.

### TECHNICAL FIELD

The present invention relates to a seed substrate and a method for producing a Group III nitride semiconductor.

### BACKGROUND ART

As a method for producing GaN, a Na flux method is known. The Na flux method is a method of growing GaN in a liquid phase by dissolving nitrogen in a mixed melt of Ga and Na. In the Na flux method, in general, a seed substrate is disposed in the mixed melt to grow GaN on the seed substrate.

As a method of growing a GaN crystal having a large area and a small dislocation density and warpage in the Na flux method, a method of using a multi-point seed (MPS) substrate as a seed substrate is known. The MPS substrate is formed by periodically arranging a large number of minute dot-shaped seed crystals on a substrate made of sapphire or the like.

Patent Literature 1 discloses that a disposition region of seed crystals in an MPS substrate is inside a circle or a regular hexagon. It is disclosed that, in the case of forming the disposition region of the seed crystals inside a circle, minute irregularities are formed on a part of an outer periphery of the grown GaN, which causes cracks. On the other hand, it is described that, in the case of forming the disposition region of the seed crystals inside a regular hexagon, the outer periphery of the grown GaN can be made linear, and cracks can be prevented.
Patent Literature 1: JP2020-132475A

### SUMMARY OF INVENTION

However, in the case of forming the disposition region of the seed crystals inside the regular hexagon as in Patent Literature 1, the irregularities on the outer periphery of the grown GaN can be reduced, but the area of GaN is reduced.

The present invention has been made in view of such a circumstance, and an object thereof is to provide a method for producing a Group III nitride semiconductor and a seed substrate capable of increasing an area of a Group III nitride semiconductor to be grown.

An aspect of the present invention relates to a method for producing a Group III nitride semiconductor including:
a substrate preparation step of preparing a seed substrate including a substrate on which a plurality of seed crystals each made of a Group III nitride semiconductor are discretely disposed; and
a crystal growth step of bringing the seed crystal into contact with a melt containing an alkali metal and a Group III metal, dissolving nitrogen in the melt, and growing a Group III nitride semiconductor on the seed crystal, in which
the plurality of seed crystals are disposed inside a disposition region which has a predetermined plane pattern, and
the disposition region has: a hexagonal region having a hexagonal shape; and at least two enlarged regions, each of which is continuous with a respective one of at least two sides of the hexagonal region including two adjacent sides among six sides of the hexagonal region, each of which is enlarged to an outer side of the hexagonal region, and each of which has a plane pattern having a side parallel to the side of the hexagonal region with which the each of the at least two enlarged regions is continuous.

Another aspect of the present invention relates to a seed substrate including:
a substrate; and
a plurality of seed crystals each made of a Group III nitride semiconductor and discretely disposed on the substrate, in which
the plurality of seed crystals are disposed inside a disposition region which has a predetermined plane pattern, and
the disposition region has: a hexagonal region having a hexagonal shape; and at least two enlarged regions, each of which is continuous with a respective one of at least two sides of the hexagonal region including two adjacent sides among six sides of the hexagonal region, each of which is enlarged to an outer side of the hexagonal region, and each of which has a plane pattern having a side parallel to the side of the hexagonal region with which the each of the at least two enlarged regions is continuous.

In the above aspects, the disposition region has: a hexagonal region having a hexagonal shape; and at least two enlarged regions, each of which is continuous with a respective one of at least two sides of the hexagonal region including two adjacent sides among six sides of the hexagonal region, each of which is enlarged to an outer side of the hexagonal region, and each of which has a plane pattern having a side parallel to the side of the hexagonal region with which the each of the at least two enlarged regions is continuous. As a result, an area of the Group III nitride semiconductor to be grown can be increased.

As described above, according to the above aspects, it is possible to provide a method for producing a Group III nitride semiconductor and a seed substrate capable of increasing an area of a Group III nitride semiconductor to be grown.

### BRIEF DESCRIPTION OF DRAWINGS

FIG. 1 is a cross-sectional view showing a configuration of a seed substrate according to a first embodiment, the cross section being perpendicular to a substrate main surface.

FIG. 2 is a plan view of the seed substrate according to the first embodiment as viewed from above.

FIG. 3 is a plan view showing a seed crystal disposition region in the seed substrate according to the first embodiment.

FIG. 4 shows a process for producing a Group III nitride semiconductor.

FIG. 5 is a diagram schematically showing an FFC step.

FIG. 6 shows plane patterns of a crystal.

FIG. 7 shows a plan view of a seed substrate according to a second embodiment as viewed from above.

FIG. 8 is a plan view of a seed substrate according to a third embodiment as viewed from above.

### DESCRIPTION OF EMBODIMENTS

A method for producing a Group III nitride semiconductor includes: a substrate preparation step of preparing a seed substrate including a substrate on which a plurality of seed crystals each made of a Group III nitride semiconductor are discretely disposed; and a crystal growth step of bringing the seed crystal into contact with a melt containing an alkali metal and a Group III metal, dissolving nitrogen in the melt, and growing a Group III nitride semiconductor on the seed crystal, in which the plurality of seed crystals are disposed inside a disposition region which has a predetermined plane pattern, and the disposition region has: a hexagonal region having a hexagonal shape; and at least two enlarged regions, each of which is continuous with a respective one of at least two sides of the hexagonal region adjacent thereto, each of which is enlarged to an outer side of the hexagonal region, and each of which has a plane pattern having a side parallel to the continuous side.

In the method for producing a Group III nitride semiconductor, the plane pattern of the enlarged region may be a trapezoid and a lower base of the trapezoid may overlap the side of the hexagonal region. By making the enlarged region have such a pattern, an area of the Group III nitride semiconductor to be grown can be further increased.

In the method for producing a Group III nitride semiconductor, a leg of the trapezoid may coincide with an m plane of the seed crystal. Irregularities on an outer periphery of the Group III nitride semiconductor after growth can be reduced.

The method for producing a Group III nitride semiconductor, a length of the lower base of the trapezoid may be shorter than a length of the side of the hexagonal region. The area of the Group III nitride semiconductor to be grown can be further increased.

In the method for producing a Group III nitride semiconductor, the side of the hexagonal region may coincide with the m plane of the seed crystal. The irregularities on the outer periphery of the Group III nitride semiconductor after growth can be reduced.

In the method for producing a Group III nitride semiconductor, a vertex formed by an upper base and a leg of the trapezoid and a vertex of the hexagonal region may be located on a circumference centered on a center of the hexagonal region. The area of the Group III nitride semiconductor to be grown can be further increased. In addition, a midpoint of the upper base of the trapezoid and a vertex formed by the lower base and the leg of the trapezoid may be located on a circumference centered on a center of the hexagonal region. It is easy to combine crystals on adjacent enlarged regions.

In the method for producing a Group III nitride semiconductor, the disposition region may have a second enlarged region that is continuous with the upper base of the trapezoid of the enlarged region, that is enlarged to an outer side of the enlarged region, and that has a plane pattern having a side parallel to the upper base. The area of the Group III nitride semiconductor to be grown can be further increased.

A seed substrate includes: a substrate; and a plurality of seed crystals each made of a Group III nitride semiconductor and discretely disposed on the substrate, in which the plurality of seed crystals are disposed inside a disposition region which has a predetermined plane pattern, and
the disposition region has: a hexagonal region having a hexagonal shape; and at least two enlarged regions, each of which is continuous with a respective one of at least two sides of the hexagonal region including two adjacent sides among six sides of the hexagonal region, each of which is enlarged to an outer side of the hexagonal region, and each of which has a plane pattern having a side parallel to the side of the hexagonal region with which the each of the at least two enlarged regions is continuous.

In the seed substrate, the plane pattern of the enlarged region may be a trapezoid and a lower base of the trapezoid may overlap the side of the hexagonal region.

In the seed substrate, a leg of the trapezoid may coincide with an m plane of the seed crystal.

In the seed substrate, a length of the lower base of the trapezoid may be shorter than a length of the side of the hexagonal region.

In the seed substrate, the side of the hexagonal region may coincide with the m plane of the seed crystal.

In the seed substrate, a vertex formed by an upper base and a leg of the trapezoid and a vertex of the hexagonal region may be located on a circumference centered on a center of the hexagonal region. In addition, a midpoint of the upper base of the trapezoid and a vertex formed by the lower base and the leg of the trapezoid may be located on a circumference centered on a center of the hexagonal region.

In the seed substrate, the disposition region may have a second enlarged region that is continuous with the upper base of the trapezoid of the enlarged region, that is enlarged to an outer side of the enlarged region, and that has a plane pattern having a side parallel to the upper base.

### First Embodiment

### 1. Overview of Flux Method

A first embodiment is a method for producing a Group III nitride semiconductor in which a Group III nitride semiconductor is grown by a flux method. The flux method is a method for epitaxially growing a Group III nitride semiconductor in a liquid phase by supplying and dissolving a nitrogen-containing gas to a mixed melt containing an alkali metal as a flux and a Group III metal as a raw material.

The Group III metal as a raw material is at least one of gallium (Ga), aluminum (Al), and indium (In), and a composition of the Group III nitride semiconductor to be grown can be controlled by the ratio thereof. GaN, AlN, InN, AlGaN, InGaN, AlGaInN, and the like can be grown. The present invention is particularly suitable for growing GaN.

The alkali metal as a flux is usually sodium (Na), but potassium (K) may be used, or a mixture of Na and K may be used. Further, lithium (Li) or an alkaline earth metal may be mixed.

Carbon (C) may be added to the mixed melt. The addition of C can increase a crystal growth rate. In addition, a dopant other than C may be added to the mixed melt for the purpose of controlling physical properties such as conductivity and magnetism of the Group III nitride semiconductor to be crystal-grown, promoting the crystal growth, preventing miscellaneous crystals, controlling a growth direction, and the like. For example, germanium (Ge) or the like can be used as an n-type dopant, and magnesium (Mg), zinc (Zn), calcium (Ca), or the like can be used as a p-type dopant.

The nitrogen-containing gas is a gas of a compound containing nitrogen molecules or nitrogen such as ammonia as constituent elements, and may be a mixed gas thereof, or the nitrogen-containing gas may be mixed with an inert gas such as a rare gas.

### 2. Structure of Seed Substrate

In the first embodiment, a seed substrate 9 is disposed in a mixed melt, and a Group III nitride semiconductor is grown on the seed substrate 9. The seed substrate 9 may be disposed in the mixed melt before being heated and pressurized, and is preferably heated and pressurized to reach a growth temperature and a growth pressure and then charged into the mixed melt. Melt back of a seed crystal 2 of the seed substrate 9 can be prevented.

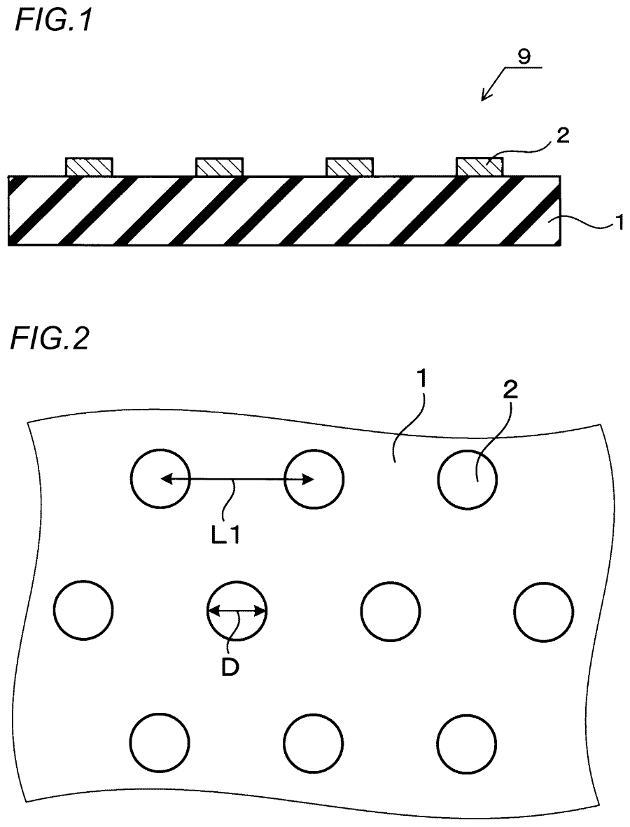

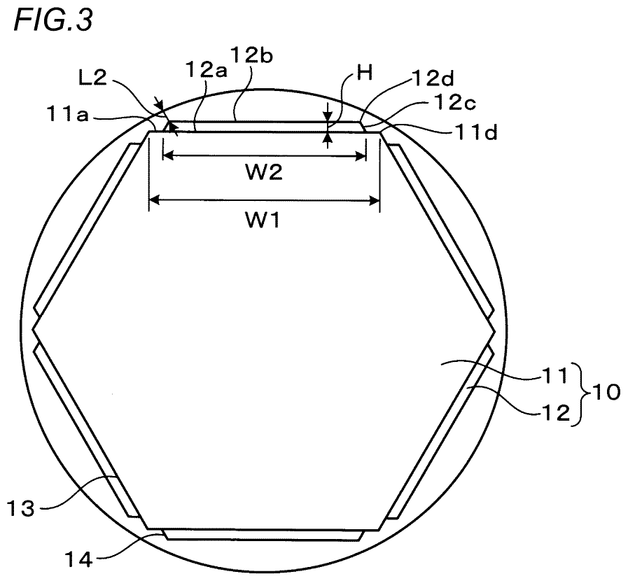

A multi-point seed (MPS) substrate is used as the seed substrate 9. The MPS substrate is a substrate in which a plurality of dot-shaped seed crystals 2 are periodically arranged on a substrate 1. FIG. 1 is a cross-sectional view of the seed substrate 9 and the cross section is perpendicular to a substrate main surface. FIG. 2 is a plan view of the seed substrate 9 as viewed from above, showing an enlarged view of a partial region. FIG. 3 is a plan view of the seed substrate 9 as viewed from above, showing a disposition region 10 of the seed crystal 2.

As the substrate 1, a Group III nitride semiconductor, sapphire, aluminum oxynitride, SiC, Si, spinel, ZnO, gallium oxide, or the like can be used. In the case of a sapphire substrate, it is, for example, a substrate having a c plane or a plane as a main surface.

A plurality of seed crystals 2 are provided on the substrate 1 via a buffer layer (not shown). The seed crystals 2 are arranged in a regular triangular lattice pattern. The buffer layer and the seed crystal 2 are each a Group III nitride semiconductor having any composition such as GaN, AlGaN, and AlN. A material of the buffer layer is appropriately selected depending on a material of the seed crystal 2. For example, when the seed crystal 2 is GaN, the buffer layer is preferably GaN. The material of the seed crystal 2 is usually a Group III nitride semiconductor having a composition same of that of the Group III nitride semiconductor to be grown by the flux method. The seed crystal 2 may be grown by any method such as a MOCVD method, a HVPE method, or a MBE method, and the MOCVD method or the HVPE method is preferred in terms of crystallinity, growth time, and the like.

A plane pattern of the seed crystal 2 is a circle or a polygon such as a regular hexagon, a square, or an equilateral triangle. FIG. 2 illustrates a case of a circle. The plane pattern of the seed crystal 2 is preferably a regular hexagon, and particularly preferably a regular hexagon in which each side is aligned with an m plane of the seed crystal 2 (each side coincides with an a-axis direction). Since the Group III nitride semiconductor is hexagonal, Group III nitride semiconductors grown from respective seed crystals 2 can be uniformly combined by forming a regular hexagon. However, it is not necessary to completely coincide with the a-axis, and a deviation of an angle of about 10 degrees is allowed. The deviation of the angle is preferably 1 degree or less.

A diameter D (diameter of a circumscribed circle in a plan view) of the seed crystal 2 is preferably 10 μm to 500 μm. Within this range, a Group III nitride semiconductor having less dislocation and warpage can be grown. The diameter D is more preferably 50 μm to 300 μm, and still more preferably 100 μm to 200 μm.

A height of the seed crystal 2 is preferably 5 μm to 50 μm. Within this range, a flatter Group III nitride semiconductor can be grown. In addition, a time required for forming the seed crystal 2 can be reduced. For the same reason, the diameter D of the seed crystal 2 is preferably 0.2 to 100 times the height of the seed crystal 2.

The seed crystals 2 are arranged in a regular triangular lattice pattern as shown in FIG. 2. It is not limited to a regular triangular lattice shape and is any as long as it is a periodic array. A pattern having high symmetry such as a square lattice shape or a regular triangular lattice shape is preferred. Group III nitride semiconductors grown from respective seed crystals 2 can be uniformly combined, and a Group III nitride semiconductor having less dislocation and warpage can be grown. In the case of a regular triangular lattice pattern, an arrangement direction thereof preferably coincides with the a-axis direction or an m-axis direction of the seed crystal 2. Coincidence here does not mean a complete coincidence, and a deviation of an angle of about 10 degrees is allowed as an error. The deviation of the angle is preferably 1 degree or less.

A distance L1 between centers of the adjacent seed crystals 2 is preferably 100 μm to 2000 μm. Within this range, a Group III nitride semiconductor having less dislocation and warpage can be grown. The distance L1 is more preferably 200 μm to 1500 μm, and still more preferably 300 μm to 1000 μm.

### 3. Regarding Disposition Region 10 of Seed Crystal 2

As shown in FIG. 3, the substrate 1 is a circle in a plan view. The disposition region 10 for disposing the seed crystal 2 is set inside the circle. A plurality of seed crystals 2 are disposed inside the disposition region 10 in a regular triangular lattice shape as described above. The seed crystals 2 being inside the disposition region 10 does not necessarily mean that all of the seed crystals 2 are inside the disposition region 10, and some of the seed crystals 2 may be located on an outer periphery of the disposition region 10.

As shown in FIG. 3, the disposition region 10 has a hexagonal region 11 and enlarged regions 12 continuous with the hexagonal region 11.

As shown in FIG. 3, the hexagonal region 11 is a regular hexagon in a plan view. The hexagonal region 11 is not necessarily a regular hexagon and may be any hexagon. However, from the viewpoint that the Group III nitride semiconductor is hexagonal and the area of the group III nitride semiconductor to be grown is as large as possible, the hexagonal region 11 is preferably a regular hexagon.

Each side 11a of an outer periphery of the hexagonal region 11 preferably coincides with the m plane of the seed crystal 2 (coincides with the a-axis direction). Coincidence here does not mean a complete coincidence, and a deviation of an angle of about 10 degrees is allowed as an error. The deviation of the angle is preferably 1 degree or less. By setting each side 11a of the outer periphery of the hexagonal region 11 as described above, irregularities on the outer periphery of the grown Group III nitride semiconductor can be reduced, and cracks can be prevented.

The enlarged regions 12 are six regions, each of which is continuous with the side 11a of the hexagon of the hexagonal region 11 and is enlarged to an outer side of the hexagonal region 11. As shown in FIG. 3, each enlarged region 12 is an isosceles trapezoid in a plan view. Hereinafter, in the isosceles trapezoid, a lower base is denoted by 12a, an upper base is denoted by 12b, a leg is denoted by 12c, and a vertex formed by the upper base 12b and the leg 12c is denoted by 12d. The lower base 12a overlaps a part of the hexagonal side 11a of the hexagonal region 11. A length W2 of the lower base 12a of the enlarged region 12 is shorter than a length W1 of the side 11a of the hexagonal region 11. For example, W2 is 0.5 to 0.9 times W1.

The upper base 12b of the trapezoid is parallel to the lower base 12a and is parallel to the side 11a of the outer periphery of the hexagonal region 11 with which the enlarged region 12 is continuous. Therefore, similar to each side 11a of the outer periphery of the hexagonal region 11, the upper base 12b of the trapezoid preferably coincides with the m plane of the seed crystal 2. Accordingly, the irregularities on the outer periphery of the Group III nitride semiconductor after growth can be reduced.

An angle as an interior angle formed by the lower base 12a and the leg 12c of the trapezoid is any as long as it is 90 degrees or less. However, the leg 12c of the trapezoid preferably coincides with the m plane of the seed crystal 2 (coincides with the a-axis direction). Coincidence here does not mean a complete coincidence, and a deviation of an angle of about 10 degrees is allowed as an error. The deviation of the angle is preferably 1 degree or less. By coinciding the leg 12c of the trapezoid with the m plane of the seed crystal 2, the irregularities on the outer periphery of the Group III nitride semiconductor after the growth can be further reduced.

A distance L2 from the vertex 12d of the enlarged region 12 to an outer periphery of the substrate 1 is preferably 0.15 mm or more. In the formation of the seed crystal 2, in a region close to the outer periphery of the substrate 1, the shape of the seed crystal 2 may be different from that of the other regions, and it may be difficult to uniformly grow the crystals from the seed crystal 2. Therefore, by setting the distance L2 to 0.15 mm or more to ensure a sufficient distance from the outer periphery of the substrate 1, the shapes of respective seed crystals 2 can be made uniform. In addition, in order to sufficiently enlarge the enlarged region 12, the distance L2 is preferably 20 mm or less. A more preferred range of the distance L2 is 2 mm to 10 mm.

A height H of the trapezoid (an interval between the lower base 12a and the upper base 12b) may be any. However, the height H is preferably set such that the distance L2 falls within the above range.

A vertex 11d of the hexagonal region 11 and the vertex 12d of the trapezoid of the enlarged region 12 are preferably on a circumference centered on a center of the hexagonal region 11. Accordingly, the area of the Group III nitride semiconductor to be grown can be further increased. Note that, it is not necessary for the vertex 11d and the vertex 12d to be on the completely same circumference, and for example, a ratio of a diameter of a circumference passing through the vertex 11d to a diameter of a circumference passing through the vertex 12d may be in a range of 0.9 to 1.1.

In addition, a midpoint of the upper base 12b of the trapezoid of the enlarged region 12 and a vertex formed by the leg 12c and the lower base 12a of the trapezoid may be located on a circumference centered on the center of the hexagonal region 11. It is easy to combine crystals grown on adjacent enlarged regions 12. In this case, it is also not necessary for the midpoint and the vertex to be on the completely same circumference, and for example, a ratio of a diameter of a circumference passing through the vertex formed by the leg 12c and the lower base 12a of the trapezoid to a diameter of a circumference passing through the midpoint of the upper base 12b of the trapezoid may be in a range of 0.9 to 1.1.

Note that, although the enlarged region 12 is an isosceles trapezoid in the first embodiment, any shape may be used as long as it is continuous with the side 11a of the hexagonal region 11, enlarged to the outer side of the hexagonal region 11, and has a plane pattern having a side parallel to the side 11a of the hexagonal region 11 continuous therewith. For example, the enlarged region 12 may be a rectangle or a trapezoid that is not an isosceles trapezoid. However, for the above reasons, an isosceles trapezoid whose leg 12c coincides with the m plane is preferred.

As described above, by providing the enlarged region 12 continuous with the hexagonal region 11 as the disposition region 10 of the seed crystal 2, the area of the Group III nitride semiconductor to be grown can be increased. In addition, the irregularities on the outer periphery of the Group III nitride semiconductor to be grown can be reduced.

### 4. Method for Producing Seed Substrate

The seed substrate 9 can be prepared, for example, as follows. First, a mask having a plurality of openings is formed on the substrate 1. The plurality of openings are arranged in a regular triangular lattice pattern. A shape of the opening is a pattern such as a circle or a regular hexagon. Further, the openings are disposed inside the disposition region 10. A material of the mask may be any material as long as it can prevent the growth of the Group III nitride semiconductor on the mask, and is, for example, SiO₂.

Next, the buffer layer and the seed crystals 2 are sequentially selectively grown on the substrate exposed to the opening by a method such as a MOCVD method or a HVPE method. Next, the mask is removed by wet etching with hydrofluoric acid or the like. With the above, the seed substrate 9 can be prepared.

### 5. Method for Producing Group III Nitride Semiconductor

Next, a method for producing a Group III nitride semiconductor according to the first embodiment will be described with reference to the drawings.

First, an atmosphere in a furnace is substituted with an inert gas, the inside of the furnace is heated, and then vacuumed to sufficiently reduce outgas components such as oxygen in the furnace.

Next, predetermined amounts of alkali metal and Group III metal are measured in a glove box in which an atmosphere such as oxygen or dew point is controlled. Thereafter, the measured predetermined amounts of the alkali metal and the Group III metal are charged into a crucible 100. An additive element such as carbon may be added as necessary.

Next, the crucible 100 into which the raw materials are charged and the seed substrate 9 are placed in a reaction vessel, which is then evacuated, and then a nitrogen-containing gas is supplied to the reaction vessel. When a pressure in the reaction vessel reaches the crystal growth pressure, a temperature of the furnace is raised to the crystal growth temperature. The crystal growth temperature is, for example, 700° C. or higher and 1000° C. or lower, and the crystal growth pressure is, for example, 2 MPa or more and 10 MPa or less. During the temperature rise process, the solid alkali metal and the solid Group III metal in the crucible 100 melt to become a liquid, and form a mixed melt 101. At this stage, the seed substrate 9 is not yet charged into the mixed melt 101.

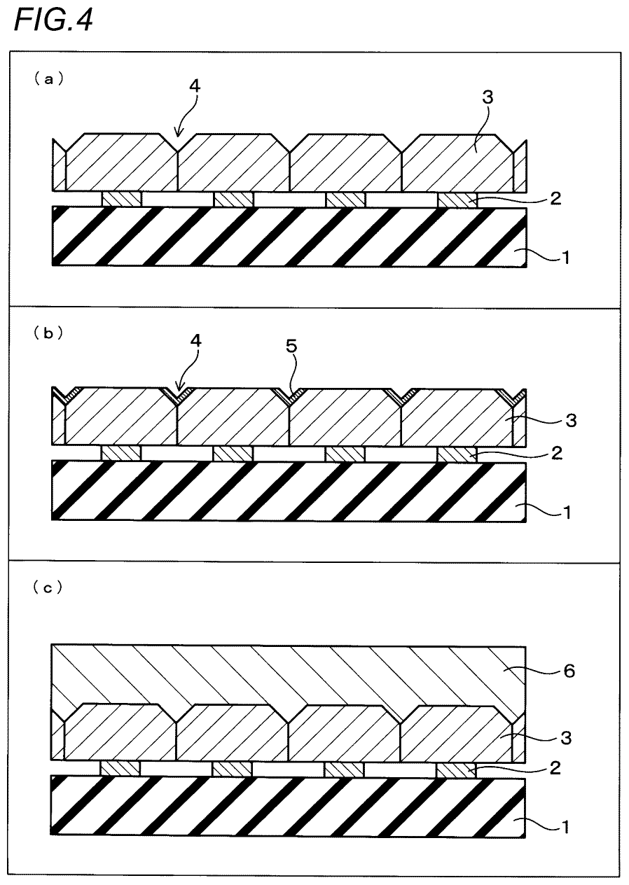

When the inside of the reaction vessel reaches the crystal growth temperature and the crystal growth pressure and the nitrogen dissolved in the mixed melt 101 is supersaturated, the seed substrate 9 is charged into the mixed melt 101 in the crucible 100. Then, a crystal 3 of the Group III nitride semiconductor grows from the seed crystal 2 of the seed substrate 9. At this time, since a (10-11) plane dominantly appears as a crystal plane, the crystal 3 has a truncated pyramid shape or a pyramid shape. The crystal 3 is grown until adjacent crystals 3 begin to combine with each other (see (a) of FIG. 4). Note that, a gap between the seed crystals 2 remains without being filled.

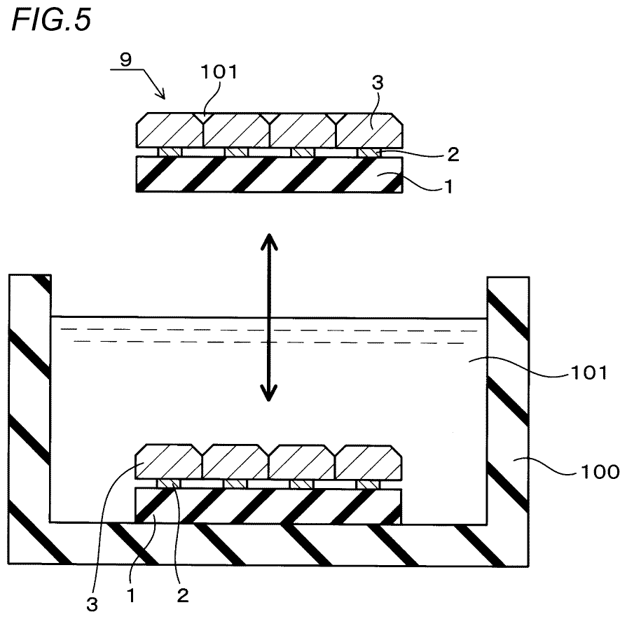

When adjacent crystals 3 begin to combine with each other, crystal growth is performed using a flux film coating (FFC) method. The FFC method is a method of repeatedly taking out the seed substrate 9 from the mixed melt 101 or charging the seed substrate 9 into the mixed melt 101 at a predetermined cycle (see FIG. 5). When adjacent crystals 3 begin to combine with each other, a recess 4 is formed on the combined surface. When the seed substrate 9 is taken out from the mixed melt 101, the mixed melt 101 is accumulated in the recess 4 between the adjacent crystals 3. Accordingly, a crystal 5 can be grown along the recess 4 (see (b) of FIG. 4).

Here, since the mixed melt 101 accumulated in the recess 4 is thin, nitrogen is likely to be supersaturated. Therefore, the crystal growth rate can be increased. On the other hand, since the amount of the accumulated mixed melt 101 is small, the amount of the Group III metal is small, and the crystal growth is not performed for a while. Therefore, the seed substrate 9 is charged into the mixed melt 101 again, and the seed substrate 9 is taken out from the mixed melt 101, whereby the mixed melt 101 containing the Group III metal is intermittently supplied to the recess 4. The FFC method is performed until the recess 4 is filled by the growth of the crystal 5. Accordingly, a crystal having a flat c plane can be grown.

Note that, although it is not always necessary to perform the FFC growth step, it is preferable to perform the FFC growth step in order to further improve flatness of the crystal and to further reduce the warpage.

When the recess 4 is filled and becomes a flat crystal plane, the seed substrate 9 is charged into the mixed melt 101 again. Then, a crystal 6 of the Group III nitride semiconductor is grown and thickened (see (c) of FIG. 4).

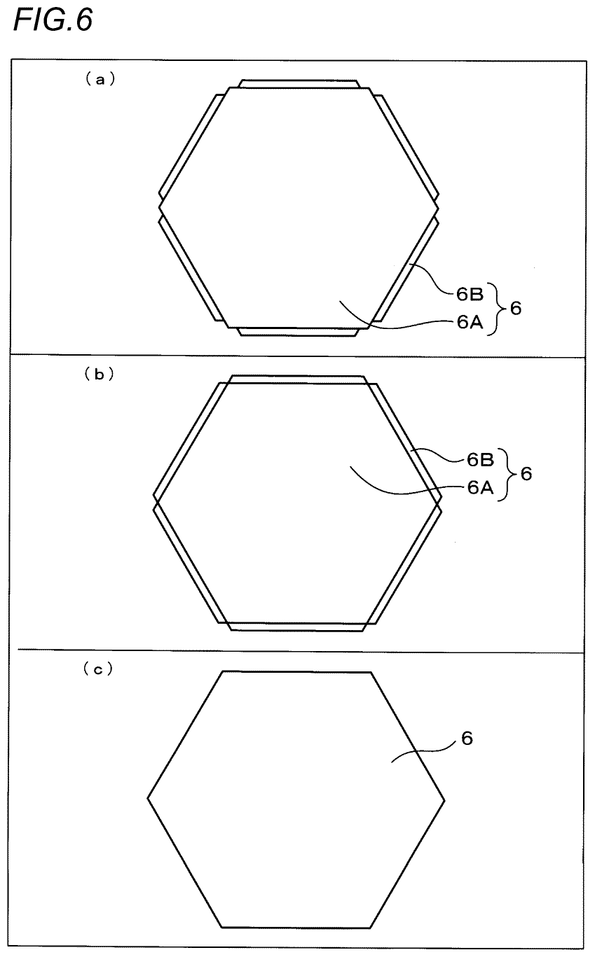

Here, as shown in (a) of FIG. 6, the crystal 6 has a plane pattern similar to the disposition region 10 of the seed crystal 2 in the early stage of growth. Thereafter, the crystal 6 grows in a direction parallel to the upper base 12b from the leg 12c of the trapezoid of the enlarged region 12, and reaches the vertex of the hexagonal region 11, as shown in (b) of FIG. 6. Then, the crystal growth from the leg 12c of the enlarged region 12 further progresses, and as shown in (c) of FIG. 6, the adjacent enlarged regions 12 are combined with each other. As a result, the crystal 6 has a hexagonal pattern wider than the hexagonal region 11 in a plan view. In this way, by forming the plane pattern of the disposition region 10 into a pattern having the hexagonal region 11 and the enlarged regions 12, the crystal 6 can be made wider than the hexagonal region 11.

Note that, depending on the growth conditions and the like, adjacent enlarged regions 12 do not combine with each other, and may form a pattern as shown in (a) of FIG. 6 or in (b) of FIG. 6. However, in this case, the crystal 6 can also be made wider than the hexagonal region 11.

When the crystal 6 grows to a desired thickness, the temperature is lowered to room temperature, the pressure is also lowered to normal pressure, and the growth of the Group III nitride semiconductor is completed. Here, the gap between the seed crystals 2 is not filled and remains. Therefore, the substrate 1 can be naturally peeled off when the temperature is lowered due to a difference in thermal expansion coefficient.

As described above, with the method for producing a Group III nitride semiconductor according to the first embodiment, since the disposition region 10 of the seed crystal 2 has the hexagonal region 11 having a hexagonal shape and the enlarged regions 12, an area of the crystal 6 after growth can be increased.

### Second Embodiment

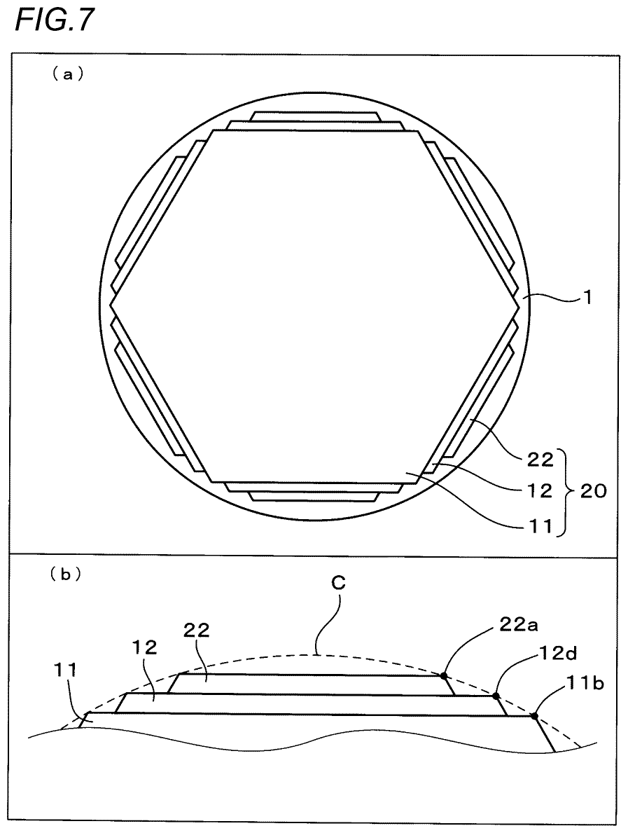

FIG. 7 shows a plan view of a disposition region 20 of the seed crystal 2 according to a second embodiment. In the second embodiment, the disposition region 10 of the seed crystal 2 of the seed substrate 9 in the first embodiment is changed to the following disposition region 20. Other configurations are the same as those of the first embodiment.

The disposition region 20 further includes an enlarged region 22 in the enlarged region 12 of the disposition region 10 in the first embodiment.

As shown in (a) of FIG. 7, the enlarged region 22 is a region continuous with the upper base 12b of the enlarged region 12 and enlarged to an outer side of the enlarged region 12. A plane pattern of the enlarged region 22 is an isosceles trapezoid. A lower base of the trapezoid of the enlarged region 22 overlaps a part of the upper base 12b of the trapezoid of the enlarged region 12. A length of the lower base of the trapezoid of the enlarged region 22 is shorter than a length of the upper base 12b of the trapezoid of the enlarged region 12. For example, it is 0.5 to 0.9 times the length of the upper base 12b. A leg of the trapezoid of the enlarged region 22 preferably coincides with the m plane, similar to the leg of the enlarged region 12.

As shown in (b) of FIG. 7, it is preferable that a vertex 22a of the enlarged region 22, the vertex 12d of the enlarged region 12, and the vertex 11d of the hexagonal region 11 are located on a circumference C whose center is the same as the center of the hexagonal region 11. The area of the Group III nitride semiconductor to be grown can be further increased. In addition, the irregularities on the outer periphery of the Group III nitride semiconductor to be grown can be reduced.

As described above, in the second embodiment, the enlarged region 22 that enlarges the enlarged region 12 is further provided, forming a two-stage structure. Therefore, the area of the Group III nitride semiconductor to be grown can be further increased.

Note that, in the second embodiment, the enlarged region 12 is further provided with the enlarged region 22 to have a two-stage structure, but a further enlarged region may be provided to provide three or more stages of enlarged regions. The area of the Group III nitride semiconductor to be grown can be further increased.

### Third Embodiment

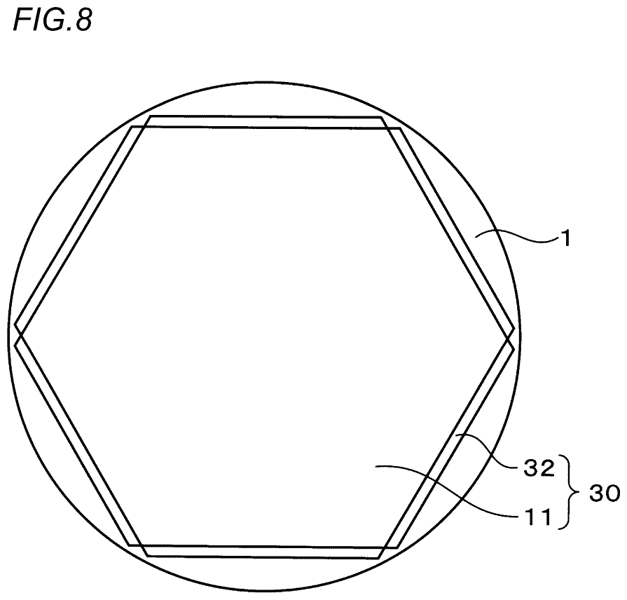

FIG. 8 is a plan view of a disposition region 30 of the seed crystal 2 according to a third embodiment. In the third embodiment, the enlarged region 12 in the first embodiment is changed to the following enlarged region 32. Other configurations are the same as those of the first embodiment.

The enlarged region 32 has an isosceles trapezoid in a plan view, and a length of a lower base coincides with the length of the side 11a of the hexagonal region 11. The rest is similar to the enlarged region 12. When the enlarged region 32 is formed to have such a plane pattern, the same effect as that of the enlarged region 12 can be obtained. That is, the area of the Group III nitride semiconductor to be grown can be increased. In addition, it is easy to combine crystals from adjacent enlarged regions 32.

In the third embodiment, similar to the second embodiment, the enlarged region 32 may also be further provided with a repeated enlarged region to have a structure of two or more stages.

### (Other Modifications)

In the first embodiment to the third embodiment, the enlarged region is provided to each of six sides of the hexagonal region 11, but this is not essential and the enlarged region may be provided to at least two adjacent sides among the six sides. However, in order to increase the area of the Group III nitride semiconductor to be grown, it is preferable to provide the enlarged regions on all sides.

### REFERENCE SIGNS LIST

1: substrate
2: seed crystal
4: recess
5, 6: crystal
9: seed substrate
10 to 30: disposition region
11: hexagonal region
12, 22, 32: enlarged region

What is claimed is:

1. A method for producing a Group III nitride semiconductor comprising:
preparing a seed substrate including a substrate on which a plurality of seed crystals, each made from a Group III nitride semiconductor, are discretely disposed; and
bringing the plurality of seed crystals into contact with a melt containing an alkali metal and a Group III metal, and dissolving nitrogen in the melt to grow a Group III nitride semiconductor on the plurality of seed crystals, wherein
the plurality of seed crystals are disposed inside a disposition region which has a predetermined plane pattern, and
the disposition region has: a hexagonal region having a hexagonal shape; and at least two enlarged regions, each of which is continuous with a respective one of at least two sides of the hexagonal region including two adjacent sides among six sides of the hexagonal region, each of which is enlarged to an outer side of the hexagonal region, and each of which has a plane pattern having a side parallel to the side of the hexagonal region with which the each of the at least two enlarged regions is continuous.

2. The method for producing a Group III nitride semiconductor according to claim 1, wherein the plane pattern of each of the at least two enlarged regions is a trapezoid, and a lower base of the trapezoid overlaps the side of the hexagonal region.

3. The method for producing a Group III nitride semiconductor according to claim 2, wherein a leg of the trapezoid coincides with an m plane of the seed crystal.

4. The method for producing a Group III nitride semiconductor according to claim 2, wherein a length of the lower base of the trapezoid is shorter than a length of the side of the hexagonal region.

5. The method for producing a Group III nitride semiconductor according to claim 1, wherein each of the six sides of the hexagonal region coincides with an m plane of the seed crystal.

6. The method for producing a Group III nitride semiconductor according to claim 2, wherein a vertex formed by an upper base and a leg of the trapezoid and a vertex of the hexagonal region are located on a circumference centered on a center of the hexagonal region.

7. The method for producing a Group III nitride semiconductor according to claim 2, wherein a midpoint of an upper base of the trapezoid and a vertex formed by a lower base and a leg of the trapezoid are located on a circumference centered on a center of the hexagonal region.

8. The method for producing a Group III nitride semiconductor according to claim 2, wherein the disposition region further has a second enlarged region that is continuous with an upper base of the trapezoid of one of the at least two enlarged regions, that is enlarged to an outer side of the one of the at least two enlarged regions, and that has a plane pattern having a side parallel to the upper base.

9. A seed substrate comprising:
a substrate; and
a plurality of seed crystals each made from a Group III nitride semiconductor and discretely disposed on the substrate, wherein
the plurality of seed crystals are disposed inside a disposition region which has a predetermined plane pattern, and
the disposition region has: a hexagonal region having a hexagonal shape;
and at least two enlarged regions, each of which is continuous with a respective one of at least two sides of the hexagonal region including two adjacent sides among six sides of the hexagonal region, each of which is enlarged to an outer side of the hexagonal region, and each of which has a plane pattern having a side parallel to the side of the hexagonal region with which the each of the at least two enlarged regions is continuous.

10. The seed substrate according to claim 9, wherein the plane pattern of each of the at least two enlarged regions is a trapezoid, and a lower base of the trapezoid overlaps the side of the hexagonal region.

11. The seed substrate according to claim 10, wherein a leg of the trapezoid coincides with an m plane of the seed crystal.

12. The seed substrate according to claim 10, wherein a length of the lower base of the trapezoid is shorter than a length of the side of the hexagonal region.

13. The seed substrate according to claim 9, wherein each of the six sides of the hexagonal region coincides with an m plane of the seed crystal.

14. The seed substrate according to claim 10, wherein a vertex formed by an upper base and a leg of the trapezoid and a vertex of the hexagonal region are located on a circumference centered on a center of the hexagonal region.

15. The seed substrate according to claim 10, wherein a midpoint of an upper base of the trapezoid and a vertex formed by a lower base and a leg of the trapezoid are located on a circumference centered on a center of the hexagonal region.

16. The seed substrate according to claim 10, wherein the disposition region further has a second enlarged region that is continuous with an upper base of the trapezoid of one of the at least two enlarged regions, that is enlarged to an outer side of the one of the at least two enlarged regions, and that has a plane pattern having a side parallel to the upper base.
